(19) United States
(12) Patent Application Publication
(10) Pub. No.: US 2018/0368273 A1
(43) Pub. Date: Dec. 20, 2018

(54) MOBILE POWER SUPPLY, DIGITAL EQUIPMENT PROTECTIVE SHELL AND ITS PRODUCTION PROCESS

(71) Applicant: Dongguan IRice Electronics Development Co., Ltd., Dongguan City (CN)

(72) Inventor: Shih-Hui CHEN, Taoyuan City (TW)

(21) Appl. No.: 15/871,809

(22) Filed: Jan. 15, 2018

(30) Foreign Application Priority Data
Jun. 14, 2017 (CN) 201710448343.8

(51) Int. Cl. H05K 5/02; A45C 11/00

(52) U.S. Cl. CPC H05K 5/0217; A45C 2011/002; A45C 11/00; H05K 5/0247

(57) ABSTRACT

The invention provides a mobile power supply, a digital equipment protective shell and a production process for producing the digital equipment protective shell. The digital equipment protective shell includes a back panel defining therein a chamber for accommodating a digital equipment, and a magnet module mounted in the back panel. The magnet module includes a plastic plate and magnets molded in the plastic plate. The magnets each have a part embedded in the plastic plate. The magnetic field of the magnets extends perpendicular to the surface of the plastic plate. By means of directly molding the magnets in the plastic plate to form the desired magnet module, the invention simplifies the assembly process of the mobile power supply and enhances the positioning stability of the magnets.

### BACKGROUND OF THE INVENTION

### 1. Field of the Invention

The present invention relates to mobile power supply technology and more particularly, to a mobile power supply, a digital equipment protective shell and a production process for producing the digital equipment protective shell.

### 2. Description of the Related Art

Portable digital equipment (such as mobile phones, MP3, MP4, PDAs, pocket PCs, handheld game consoles, etc.) have become more and more popular. Due to continuous development of functions and display technologies, the frequency of use of portable digital equipment is higher and higher, and the using time is longer and longer, and the corresponding power consumption is also getting faster and faster. In order to solve the problem of battery life in digital equipment without charging, many mobile power supply designs have been created. A mobile power supply is the combination of mobile power supply and battery charger, which can be used anywhere to provide power supply to a portable digital equipment, or to charge the battery of a portable digital equipment. When using a mobile power supply to provide power supply to a portable digital equipment, a data cable shall be used, i.e., the data cable must be connected with its one end to the mobile power supply and its other end to the portable digital equipment so that power supply can be transmitted from the mobile power supply to the portable digital equipment. This operation procedure is complicated.

Further, a mobile power supply and a portable digital equipment protective shell can be respectively provided with magnets so that the portable digital equipment and the mobile power supply can be firmly secured together by magnetic attracting when using the mobile power supply to charge the battery of the portable digital equipment. When making a magnet-provided portable digital equipment protective shell or mobile power supply, it is necessary to make magnet mounting holes on the shell or housing, and then to install magnets individually in the magnet mounting holes. In this preparation method, the magnet mounting holes and the magnets must perfectly match in size and shape. Further, the assembly process is also complicated (for example, it must ensure that the multiple magnets are installed in place, and the multiple magnets are installed in the same direction, etc. In addition, in the digital equipment protective shell and mobile power supply described above, the combination of the magnets and the shell/housing is not stable and will increase the thickness of the entire mobile power supply.

### SUMMARY OF THE INVENTION

The present invention has been accomplished under the circumstances in view. It is therefore the main object of the present invention to provide a mobile power supply, a digital equipment protective shell and a production process for producing the digital equipment protective shell, which avoids the problem of complicated prior art mobile power supply installation procedure.

To achieve this and other objects of the present invention, the invention provides a mobile power supply, which comprises a magnet module mounted in a back panel of a housing thereof. The housing consists of a front panel and the back panel. The magnet module comprises a plastic plate, and a plurality of magnets molded in the plastic plate. The magnetics are respectively partially embedded in the plastic plate. Further, the magnetic field of the magnets extends perpendicular to the surface of the plastic plate.

Further, in one embodiment of the present invention, the plastic plate of the magnet module is the back panel of the housing, and the magnets are partially embedded in an inner side of said back panel. In another embodiment of the present invention, the plastic plate of the magnet module is independent of the back panel of the housing magnet module and affixed to an inner side of the back panel.

The invention also provided a digital equipment protective shell, which comprises a back panel, and a chamber defined in the back panel for accommodating a digital equipment. The back panel is equipped with a magnet module. The magnet module comprises a plastic plate, and a plurality of magnets molded in the plastic plate. The magnets are respectively partially embedded in the plastic plate and fixedly secured to said plastic plate. Further, the magnetic field of the magnets extends perpendicular to the surface of the plastic plate.

In one embodiment of the present invention, the plastic plate of the magnet module is the back panel, and the magnets are respectively embedded in an inner side of the back panel.

In another embodiment of the present invention, the plastic plate of the magnet module is independent of the back panel and affixed to an inner side of the back panel.

Preferrably, the magnets each have a part thereof protruding over the surface of the plastic plate. Preferably, the back panel comprises a plurality of recessed holes located on an inner side thereof for accommodating the protruding part of each magnet.

Preferrably, the plastic plate further has an electrical connector molded therein. The electrical connector comprises an electrode surface. The electrode surface comprises a plurality of electrodes exposed to the outside of the back panel.

Preferrably, the thickness of the plastic plate is smaller than the thickness of the magnets, and the magnets are magnetized after formation of the magnet module.

Preferrably, each magnet has grooves located on one side thereof and embedded in the plastic plate.

The invention also provides a production process for producing the digital equipment protective shell. The production process comprises the steps of:

(a) putting a plurality of magnetic material pieces in a cavity of a mold at selected locations;

(b) filling a molten plastic in the cavity of the mold to mold a magnet module, and then removing the magnet module from the mold after cooling; and

(c) magnetizing the magnetic material pieces of the magnet module.

By means of molding the magnets and the plastic plate together in one time, the invention simplifies the assembly process of the mobile power supply and enhances the positioning stability of the magnets. Further, because the magnets of the magnet module are magnetized after formation of the magnet module, the invention avoids human magnetization installation errors.

Other advantages and features of the present invention will be fully understood by reference to the following specification in conjunction with the accompanying drawings.

### BRIEF DESCRIPTION OF THE DRAWINGS

FIG. 1 is a schematic front elevational view of a magnetically digital equipment protective shell in accordance with a first embodiment of the present invention.

FIG. 2 is a schematic back elevational view of the magnetically digital equipment protective shell shown in FIG. 1.

FIG. 3 is a schematic front elevational view of a magnetically digital equipment protective shell in accordance with a second embodiment of the present invention.

FIG. 4 is an exploded view of the magnetically digital equipment protective shell in accordance with the second embodiment of the present invention.

FIG. 5 is a schematic front elevational view of a mobile power supply in accordance with a first embodiment of the present invention.

FIG. 6 is a schematic front elevational view of a mobile power supply in accordance with a second embodiment of the present invention.

FIG. 7 is an exploded view of the mobile power supply in accordance with the second embodiment of the present invention.

### DETAILED DESCRIPTION OF THE PREFERRED EMBODIMENT

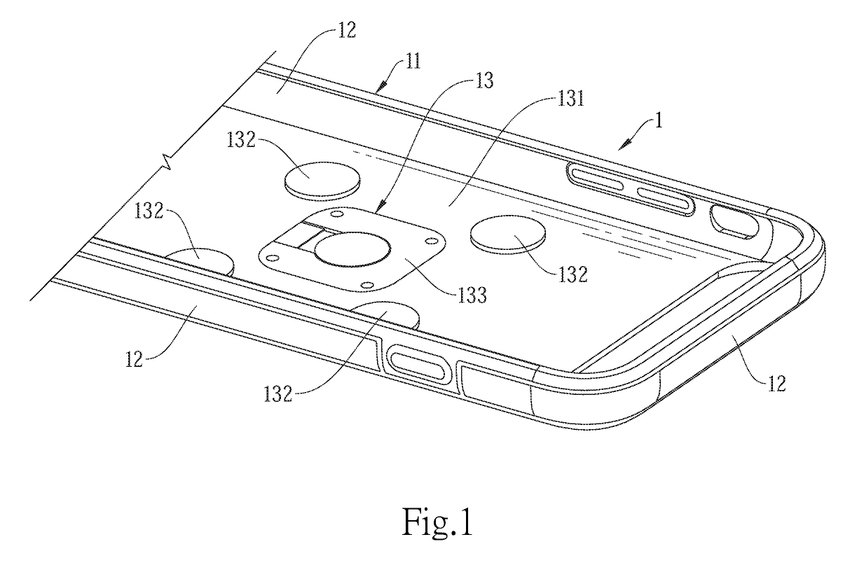

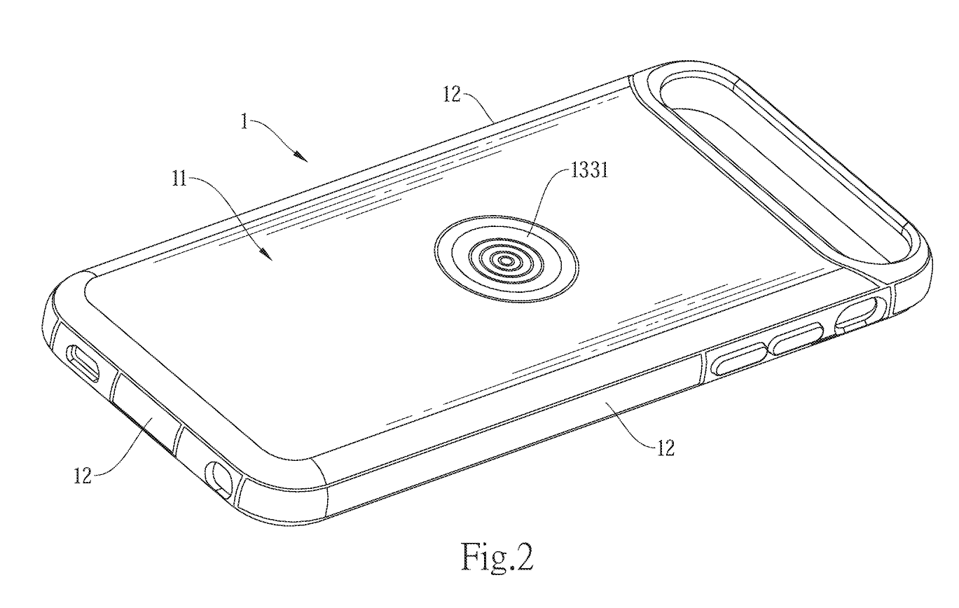

Referring to FIGS. 1 and 2, a digital equipment protective shell 1 in accordance with a first embodiment of the present invention is shown. The digital equipment protective shell 1 is adapted for attaching to a digital equipment (such as mobile phone) to protect the digital equipment against damage and to facilitate charging the digital equipment.

In this embodiment, the digital equipment protective shell 1 comprises a back panel 11, a wrap-around frame 12 wrapped around the back panel 11, and a chamber defined within the back panel 11 and the wrap-around frame 12 for accommodating a digital equipment digital equipment. After insertion of a digital equipment in the chamber within the back panel 11 and the wrap-around frame 12, the wrap-around frame 12 surrounds the peripheral surface or a part of the peripheral surface of the digital equipment.

The digital equipment protective shell 1 further comprises a magnet module 13 mounted in the back panel 11. The magnet module 13 comprises a plastic plate 131 and a plurality of magnets 132. The magnets 132 and the plastic plate 131 are made in integrity using molding technology, i.e., the magnets 132 are molded in the plastic plate 131. The magnets 132 each have a part embedded in the plastic plate 131 and fixedly secured to the plastic plate 131. Further, the magnetic field of the magnets 132 extends perpendicular to the surface of the plastic plate 131.

In particular, the magnets 132 are made of a magnetic material selected from the group of ferrites, neodymium iron boron, alnico, samarium cobalt and plastic magnets.

These magnets 132 are non-magnetic before the molding process, and they are magnetized to create a magnetic field after the molding process of the magnet module 13. Through the above-mentioned method of magnetization after molding, the problem of complicated individual magnet installation procedure and human polarization installation error can be avoided.

In this embodiment, the plastic plate 131 of the magnet module 13 is a part of the back panel 11, i.e., the magnets 132 and the back panel 11 are molded together so that the magnets 132 are partially embedded in the back panel 11. This mounting arrangement greatly enables the thickness of the back panel 11 to be minimized, reducing the overall thickness of the digital equipment protective shell 1 and allowing the magnets 132 to partially protrude over the inner surface of the back panel 11 (the thickness of the back panel 11 is smaller than the thickness of the magnets 132). Further, in order to enhance the bonding strength between the magnets 132 and the back panel 11 and to prevent falling of the magnets 132 from the back panel 11, a reinforcing structural can be added to the back panel 11 corresponding to the positions of the magnets 132. In actual application, the magnets 132 can be fully embedded in the back panel 11, however, this arrangement will greatly increase the thickness of the back panel 11.

The magnet module 13 further comprises an electrical connector 133 molded with the magnets 132 in the back panel 11. The electrical connector 133 comprises an electrode surface 1331 exposed to the outside of the back panel 11, as shown in FIG. 2. Specifically, the electrode surface 1331 can be recessed into the surface of the back panel 11, protruded over the surface of the back panel 11, or maintained in flush with the surface of the back panel 11.

The electrode surface 1331 provides a plurality of electrodes that constitute a pattern, for example, a pattern of concentric rings. In this embodiment, a connection terminal (such as male plug) is provided in the digital equipment protective shell 1 for the connection of a digital equipment. The electrodes of the electrode surface 1331 are connected to the connection terminal directly through a bus line or via a control circuit incorporated circuit board. Thus, when a digital equipment is mounted in the chamber inside the digital equipment protective shell 1, the connection terminal is inserted into the mating connection port of the digital equipment. At this time, the digital equipment can be connected to an external equipment through the electrodes of the electrode surface 1331 for battery charging or data exchange. As the magnets 132 are mounted in the back panel 11, the back panel 11 can be firmly secured to the surface of a mating external equipment (battery charger or other electronic device) by magnetic attraction, keeping the electrode surface 1331 of the electrical connector 133 in electrical conduction with the external equipment.

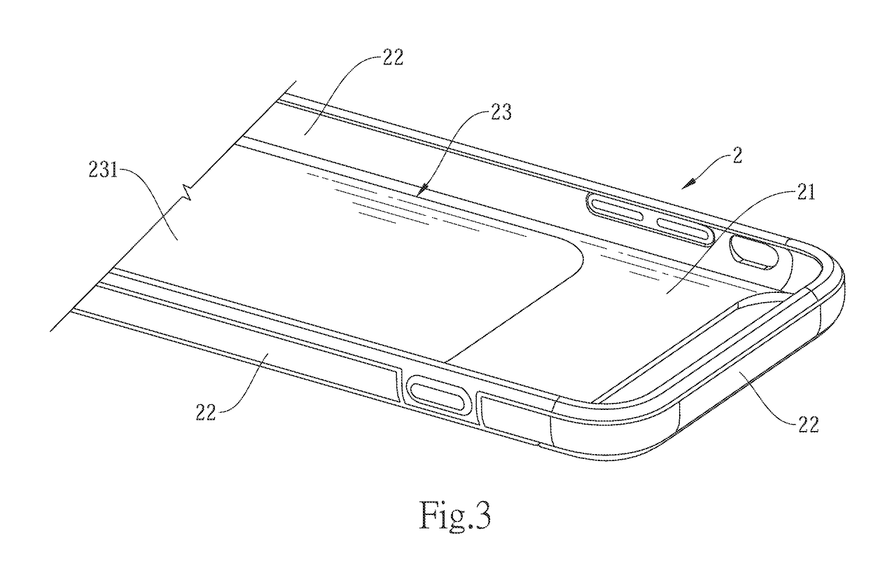

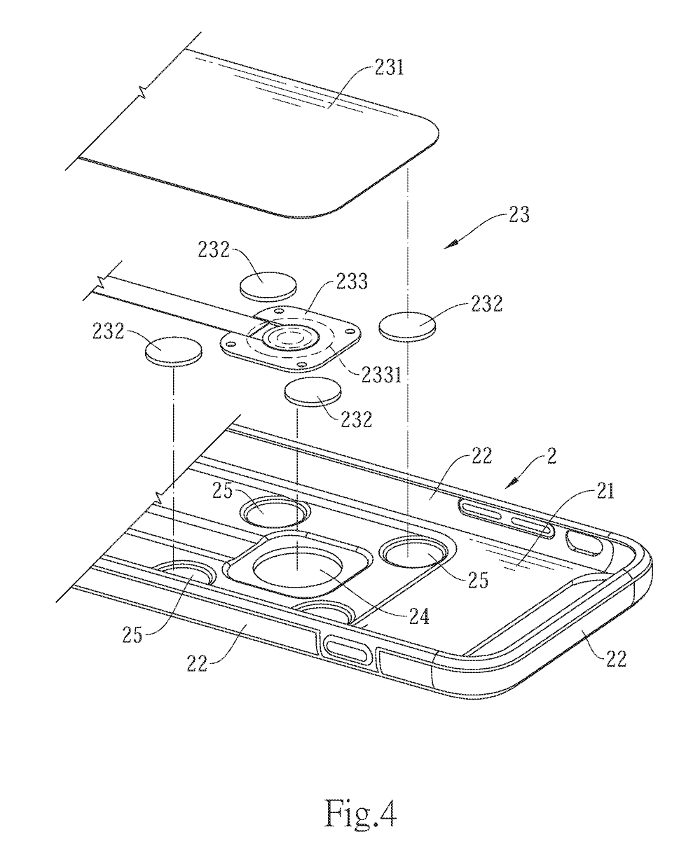

Referring to FIGS. 3 and 4, a digital equipment protective shell 2 in accordance with a second embodiment of the present invention is shown. The second embodiment is substantially similar to the aforesaid first embodiment with the exception that the magnet module 23 is independent of the back panel 21, i.e., the plastic plate 231 of the magnet module 23 is independent of the back panel 21 (in this case, the back panel 21 can be made of a metal material, or separately made from a plastic material by molding. The magnets 232 are directly molded in the plastic plate 231, and then the plastic plate 231 is affixed to the inner side of the back panel 21.

In order to reduce the thickness of the plastic plate 231, the back panel 21 provides a plurality of recessed holes 25. When fastening the plastic plate 231 to the back panel 21, the protruding part of each magnet 232 over the surface of the plastic plate 231 is press-fitted into one respective recessed hole 25 of the back panel 21. Of course, in actual application, the magnets 232 can be completely embedded in the plastic plate 231.

Similarly, an electrical connector 233 is molded with the magnets 232 in the plastic plate 231. The electrical connector 233 comprises an electrode surface 2331. Further, the back panel 21 has an opening 24. As the plastic plate 231 is affixed to the back panel 21, the electrode surface 2331 exposes to the outside of the back panel 21 through the opening 24.

Further, in order to enhance the bonding strength between the magnets (132;232) and the plastic plate (131;231), the magnets (132;232) are processed to provide grooves (or coated surface) so that the applied molten plastic can fill up the grooves during the molding process. Further, the magnets (132;232) can be configured to exhibit a circularly stepped shape so that the relatively larger outer diameter portions of the magnets (132;232) can be embedded in the plastic plate (131;231) during the molding process, enabling the relatively smaller outer diameter portions of the magnets (132;232) can be embedded in the plastic plate (131;231) to protrude over the surface of the plastic plate (131;231).

The invention also provide a production process for producing the aforesaid digital equipment protective shell. This production process includes the steps of:

(a) putting a plurality of magnetic material pieces in the cavity of a mold at predetermined locations;

(b) melting a prepared plastic material into a molten plastic and then filling the molten plastic in the cavity of the mold to create a magnet module (13;23), and then removing the magnet module (13;23) from the mold after cooling; and

(c) magnetizing the magnetic material pieces of the magnet module (13;23).

Further, the magnetic material pieces prepared in step (a) can be selected from the group of ferrite, neodymium iron boron, alnico, samarium cobalt and plastic magnets; the applied molten plastic can be molded to form the back panel (11;21) and wrap-around frame (12;22) of the digital equipment protective shell (1;2), or simply to form the plastic plate (131;231).

Further, the magnetic material pieces prepared in step (a) can be configured to exhibit a circularly stepped shape so that the relatively larger outer diameter portions of the magnetic material pieces can be embedded in the plastic plate (131;231) during the molding process, enabling the relatively smaller outer diameter portions of the magnetic material pieces can be embedded in the plastic plate (131;231) to protrude over the surface of the plastic plate (131;231). Alternatively, the magnetic material pieces prepared in step (a) can be configured to exhibit a cylindrical shape.

Further, the electrical connector (133;233) having an electrode surface (1331;3231) and the magnetic material pieces can be all put in the cavity of the mold at respective predetermined locations, enabling the electrical connector (133;233) to be molded in the plastic plate (131;231).

Further, when magnetizing in step (c), the magnetic pole of the magnetic material pieces can be changed as needed.

The above-described magnet module (13;23) preparation process can avoid the problem of complicated individual magnet installation procedure and human polarization installation error. If finished magnets are used and molded in the plastic plate (131;231), the high temperature during the molding process can affect the magnetity of the magnets, and the magnets can be reversely positioned in the mold due to human errors.

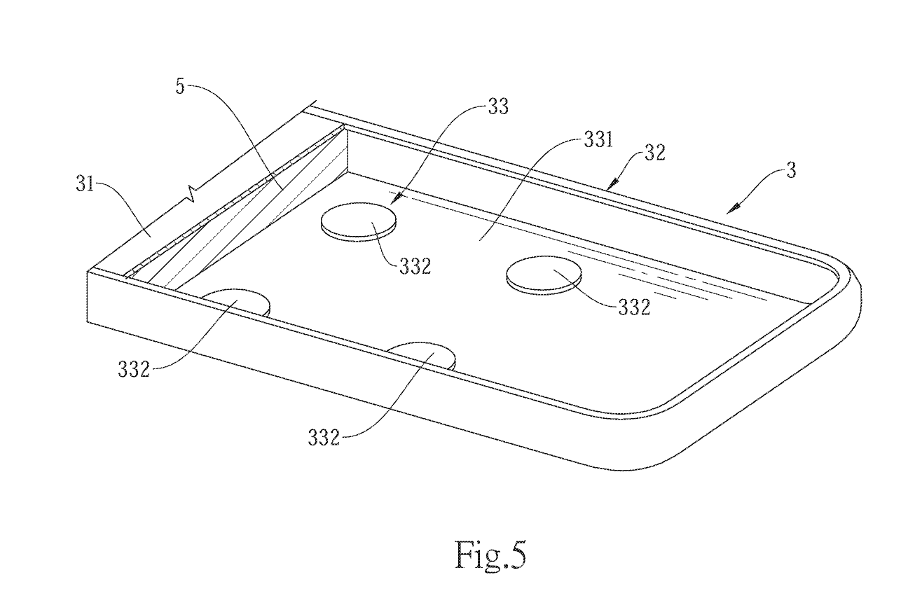

Referring to FIG. 5, the present invention also provides a mobile power supply 3 for use with the digital equipment protective shell (1;2). The mobile power supply 3 comprises a housing consisting of a front panel 31 and a back panel 32, a battery 5 mounted in the housing, and a magnet module 33 mounted in the back panel 32. The magnet module 33 comprises a plastic plate 331, and a plurality of magnets 332 molded in the plastic plate 331. The magnets 332 each have a part embedded in the plastic plate 331 and fixedly secured to the plastic plate 331. Further, the magnetic field of the magnets 332 extends perpendicular to the surface of the plastic plate 331. Further, the plastic plate 331 of the magnet module 33 can be the back panel 32 of the housing of the magnet module 33. Further, the magnets 332 are embedded in the inner side of the back panel 32.

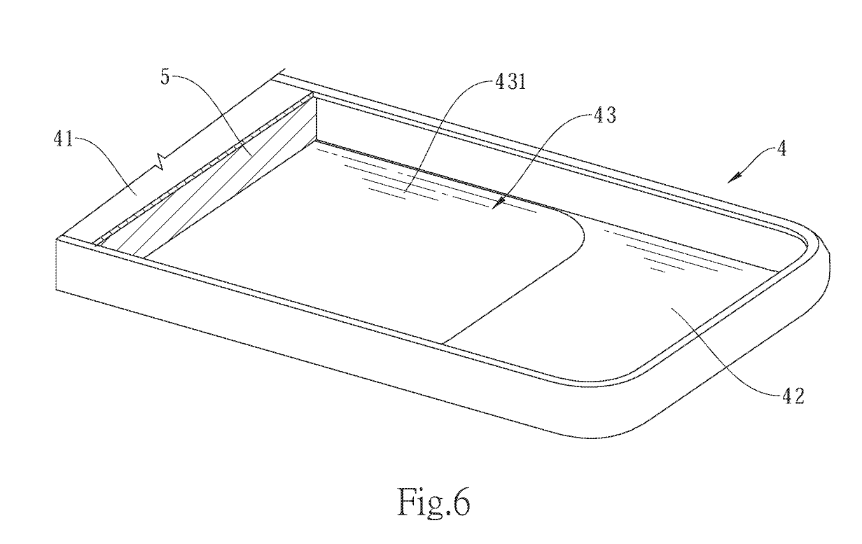

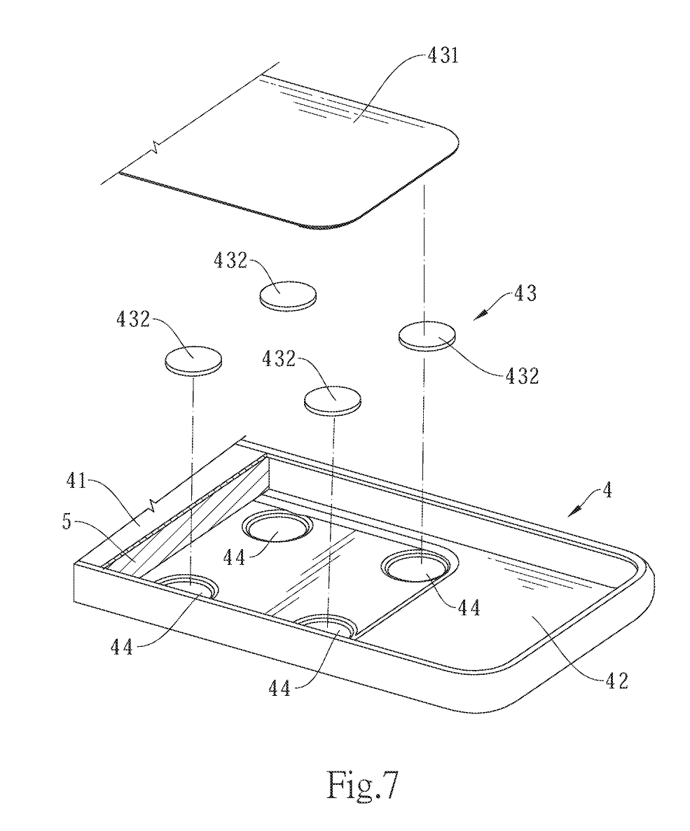

FIGS. 6 and 7 illustrate an alternate form of mobile power supply in accordance with the present invention, this alternate form of mobile power supply, referenced by 4, is substantially similar to that shown in FIG. 5 with the exception that the plastic plate 431 of the magnet module 43 is independent of the housing (in this case, the housing of the mobile power supply can be made of a metal materials, or molded from a plastic material). The back panel 41 carrying the magnets 432 is affixed to the inner side of the plastic plate 431. In actual application, in order to minimize the thickness of the plastic plate 431, the magnets 432 each have a part protruding over the surface of the plastic plate 431; correspondingly, the back panel 41 provides a plurality of recessed holes 44 in the inner side thereof. When fastening the plastic plate 431 to the back panel 41, the protruding part of each magnet 432 is press-fitted into one respective recessed hole 44 in the back panel 41.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A mobile power supply, comprising a magnet module mounted in a back panel of a housing thereof, said housing consisting of a front panel and said back panel, said magnet module comprising a plastic plate and a plurality of magnets molded in said plastic plate, said magnetics being respectively partially embedded in said plastic plate, the magnetic field of said magnets extending perpendicular to the surface of said plastic plate.

2. The mobile power supply as claimed in claim 1, wherein said plastic plate of said magnet module is the said back panel of said housing; said magnets are partially embedded in an inner side of said back panel.

3. The mobile power supply as claimed in claim 1, wherein said plastic plate of said magnet module is independent of the said back panel of said housing magnet module and affixed to an inner side of said back panel.

4. A digital equipment protective shell, comprising a back panel and a chamber defined in said back panel for accommodating a digital equipment, wherein said back panel is equipped with a magnet module, said magnet module comprising a plastic plate and a plurality of magnets molded in said plastic plate, said magnets being respectively partially embedded in said plastic plate and fixedly secured to said plastic plate, the magnetic field of said magnets extending perpendicular to the surface of said plastic plate.

5. The digital equipment protective shell as claimed in claim 4, wherein said plastic plate of said magnet module is the said back panel; said magnets are respectively embedded in an inner side of said back panel.

6. The digital equipment protective shell as claimed in claim 4, wherein said plastic plate of said magnet module is independent of said back panel and affixed to an inner side of said back panel.

7. The digital equipment protective shell as claimed in claim 4, wherein said plastic plate of said magnet module is independent of said back panel and affixed to an inner side of said back panel; said magnets each have a part thereof protruding over the surface of said plastic plate; said back panel comprises a plurality of recessed holes located on an inner side thereof for accommodating the protruding part of each said magnet.

8. The digital equipment protective shell as claimed in claim 4, wherein said plastic plate further has an electrical connector molded therein, said electrical connector comprising an electrode surface, said electrode surface comprising a plurality of electrodes exposed to the outside of said back panel.

9. The digital equipment protective shell as claimed in claim 4, wherein the thickness of said plastic plate is smaller than the thickness of said magnets, and said magnets are magnetized after formation of said magnet module.

10. The digital equipment protective shell as claimed in claim 4, wherein each said magnet has grooves located on one side thereof and embedded in said plastic plate.

11. A production process for producing the digital equipment protective shell as claimed in claim 4, comprising the steps of:
(a) putting a plurality of magnetic material pieces in a cavity of a mold at selected locations;
(b) filling a molten plastic in said cavity of said mold to mold a magnet module and then removing said magnet module from said mold after cooling; and
(c) magnetizing said magnetic material pieces of said magnet module.
